(19) United States
(12) Patent Application Publication
(10) Pub. No.: US 2002/0163959 A1
(43) Pub. Date: Nov. 7, 2002

(54) Shortening impulse reponse fliter (SIRF) and design technique therefor

(76) Inventor: Khalil Camille Haddad, Morganville, NJ (US)

Correspondence Address: Ryan, Mason & Lewis, LLP, Suite 205, 1300 Post Road, Fairfield, CT, 06430, US

(21) Appl. No.: 09/803,801

(22) Filed: Mar. 12, 2001

(51) Int. Cl. H03K 5/159

(52) U.S. Cl. 375/229

(57) ABSTRACT

Shortening impulse response filters (SIRF) are disclosed that satisfy constraints in both the time and frequency domains. In addition, methods and apparatus are disclosed for determining the coefficient values for SIRF filters. The disclosed SIRF filters shorten the channel impulse response in the time domain while also providing a frequency response that does not attenuate or amplify the received signal. One or more sets define constraints that the SIRF filter must satisfy in the time domain, and one or more sets define constraints that the SIRF filter must satisfy in the frequency domain. By varying the sets utilized to define the time and frequency domain constraints, SIRF filters having a linear or non-linear phase response may be obtained. The intersection of the various sets defines the coefficients for the SIRF filters. Vector space projection methods are utilized to determine the intersection set.

### FIELD OF THE INVENTION

The present invention relates to techniques for shorting the impulse response of communication systems, such as discrete multi-tone (DMT) and orthogonal frequency division multiplexing (OFDM) communication systems, and more particularly, to methods and apparatus for designing a shortening impulse response filter (SIRF).

### BACKGROUND OF THE INVENTION

It is well known that most communication channels are dispersive in nature and introduce a number of distortions. Thus, signals arriving at a receiver are typically corrupted by intersymbol interference (ISI), crosstalk, echo, and other noise. Thus, receivers must jointly equalize the channel, to compensate for such intersymbol interference and other distortions, and decode the encoded signals at increasingly high clock rates.

To overcome the effects of intersymbol interference, any two adjacent symbols in a conventional DMT or OFDM communication system are separated by a guard period (i.e., a cyclic prefix (CP)). In addition to providing a mechanism for frame synchronization, the guard interval insures that samples from one symbol block do not interfere with the samples of another block. The length of the impulse response of the physical channel determines the required length of the guard interval. Using a long guard interval, however, reduces the effective throughput of the transceiver. Thus, to avoid using a long guard interval, filters are employed to shorten the channel impulse response and thereby allowing the use of a shorter guard interval. More specifically, time domain linear filters, often referred to as shortening impulse response filters (SIRFs) or time domain equalizers (TDQs), are typically employed to shorten the channel impulse response.

A number of techniques have been proposed or suggested for designing TDQ filters. For a detailed discussion of a number of such filter design techniques, see, for example, J. W. P. Melsa and R. C. Younce, “Impulse Response Shortening for Discrete Multitone Tranceivers,” IEEE Trans., COM-44, (12), 1662-1672 (1996); or N. Al-Dahir and J. M. Cioffi, “Stable Pole-Zero Modeling of Long FIR Filters With Application to the MMSE-DFE,” IEEE Trans., COM-45, (5) 508-513 (1997), each incorporated by reference herein. Generally, these filter design algorithms are typically based on least mean square (LMS) or eigenvector calculus. While these filter design algorithms are capable of producing very good TDQ filters, they suffer from a number of limitations, which if overcome, could greatly improve their ability to shorten the channel impulse response and otherwise improve system performance. Specifically, since these filter design algorithms have little, if any, control over the frequency response, they may produce a frequency response with nulls in the pass-band that degrade the signal-to-noise ratio (SNR) of the received signal, translating into a lower bit rate throughput. It has been found, however, that removing the nulls in the pass-band is a difficult problem, often requiring a trial and error solution. In addition to the null problem, the frequency response in unpredictable and severe attenuation and amplification variations could result from call to call.

A need therefore exists for improved techniques for designing SIRF filters. A further need exists for SIRF filters that satisfy constraints in both the time and frequency domains to provide improved performance. Yet another need exists for methods and apparatus for determining coefficient values for SIRF filters that shorten the channel impulse response in the time domain while also providing a frequency response that does not attenuate the received signal.

### SUMMARY OF THE INVENTION

Generally, a method and apparatus are disclosed for determining parameters for SIRF filters. According to one aspect of the invention, filter coefficients for SIRF filters are determined that satisfy constraints in both the time and frequency domains to provide improved performance. More specifically, SIRF filters are disclosed that shorten the channel impulse response in the time domain while also providing a frequency response that does not attenuate or amplify the received signal.

One or more sets are established to define constraints that the SIRF filter must satisfy in the time domain, and one or more sets are established to define constraints that the SIRF filter must satisfy in the frequency domain. An SIRF filter satisfying both frequency and time constraints is obtained by determining the intersection of the various sets. By varying the sets utilized to define the time and frequency domain constraints, SIRF filters having a linear or non-linear phase response may be obtained. Vector space projection method is an iterative algorithm applied to the sets until the algorithm converges to a solution, i.e., the intersection if the sets intersect, or to a point with minimum summing distance to all sets if the sets do not intersect. In the case of SIRF design, the solution of the algorithm is the filter coefficients.

A more complete understanding of the present invention, as well as further features and advantages of the present invention, will be obtained by reference to the following detailed description and drawings.

### BRIEF DESCRIPTION OF THE DRAWINGS

FIG. 1 illustrates a variable shortening impulse response filter applied to a signal on a dispersive communication channel to shorten the channel impulse response in accordance with the present invention;

FIG. 2 is a schematic block diagram illustrating a modem in which the present invention may be employed.

FIG. 3 is a flow chart describing the filter coefficient determination process incorporating features of the present invention;

FIGS. 4A through 4E, collectively, illustrate exemplary pseudo-code for generating a non-linear SIRF filter; and

FIG. 5 illustrates the trajectory of iteration in VSPM for two sets until the algorithm converges to the intersection, i.e., the solution.

### DETAILED DESCRIPTION

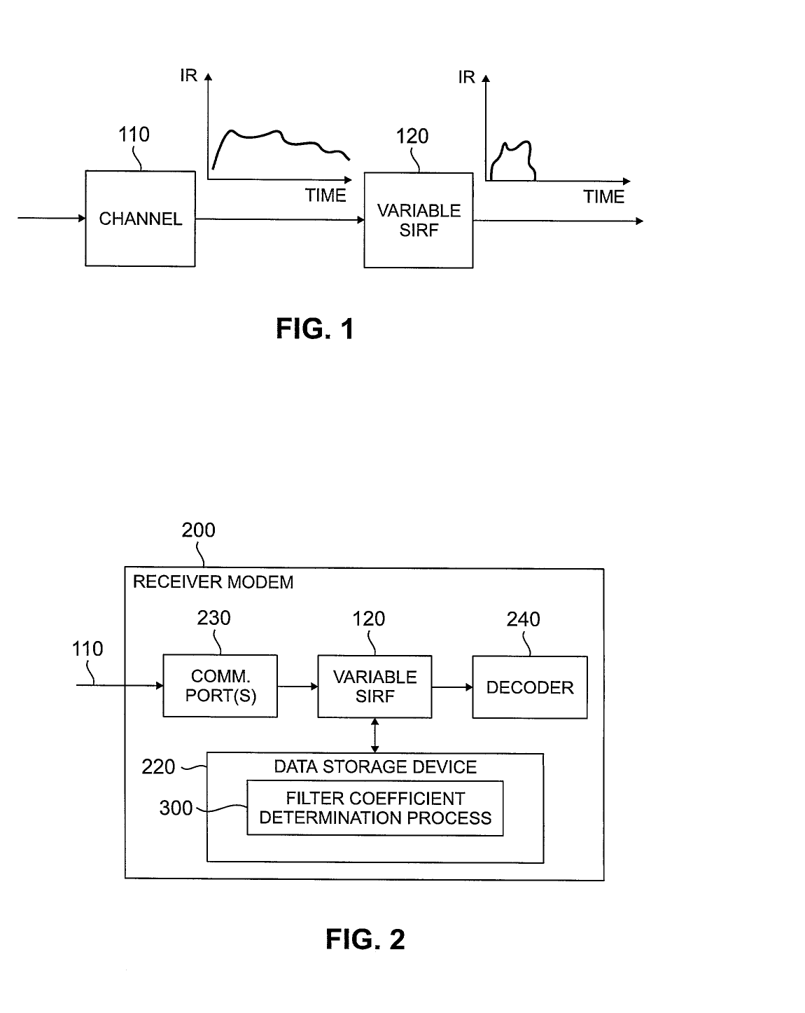

FIG. 1 illustrates the use of a variable shortening impulse response filter 120 on a dispersive communication channel 110 to shorten the channel impulse response 130a, b, in accordance with the present invention. According to one aspect of the present invention, the variable SIRF filter 120 can satisfy constraints in both the time and frequency domains to provide improved performance. Although described in connection with exemplary DMT and OFDM communication systems, it will be understood that the present invention is equally applicable to any environment where it is desirable to shorten an impulse response.

### Vector Space Projection Methods (VSPM)

According to one aspect of the present invention, vector space projection methods are employed to design SIRF filters. For a detailed discussion of vector space projection methods (VSPM), see, for example, L. M. Bregman, “Finding the Common Point of Convex Sets by the Method of Successive Projections, “Dokl. Akad. Nauk USSR, Vol. 162, No. 3, 487 (1965), incorporated by reference herein. VSPM techniques find a mathematical object (in this case a set of coefficients) in a proper vector space that satisfies multiple constraints. When all the constraint sets are convex and have a nonempty intersection, the VSPM becomes a powerful theory in finding the objects that satisfy all the constraints. As discussed further below, vector space projection methods employ an iterative algorithm that will converge to a set of finite impulse response (FIR) coefficients that satisfies constraints in the time domain (e.g., shortening the channel impulse response) and constraints in the frequency domain spectrum.

Traditionally, VSPM techniques have been employed to design constrained FIR filters that are tailored to specific applications. See, K. C. Haddad, “Constrained FIR Filter Design by the Method of Vector Space Projections,” IEEE Trans. on Circuit and Systems II: Analog and Digital Signal Processing, Vol. 47, No. 8 (August 2000), incorporated by reference herein. In the context of the present invention, where VSPM techniques are employed to design an SIRF filter, two (or more) convex sets representing the constraints in time and frequency domains and corresponding projection operators have been mathematically formulated. A first convex set defines the constraints that the SIRF filter 120 must satisfy in the time domain, such that when the filter is convolved with the impulse response, the impulse response is shortened. Likewise, a second convex set defines the constraints that the SIRF filter 120 must satisfy in the frequency domain, such as a low, high or band pass band. Pᵢ is defined to be the projection operator onto the set Cᵢ. Thus, to obtain an SIRF filter satisfying both frequency and time constraints, an intersection of both sets is required.

### Designing the SIRF Filter

Generally, the present invention designs a variable SIRF filter 120 having an impulse response, h, of length N to shorten the impulse response of a channel s, where

h=(h(0), h(1), . . . , h(N−1)).

In the frequency domain, h becomes:

$$\begin{matrix}H ( ω ) = {\sum }_{0}^{N - 1} h ( n ) {ⅇ}^{- jω n} = A ( ω ) {ⅇ}^{jΦ ( ω )} , where \\ A ( ω ) = {\sum }_{0}^{N / 2 - 1} 2 h ( n ) cos [ ( n - \frac{N - 1}{2} ) ω ] and \\ Φ ( ω ) = - \frac{N - 1}{2} ω ( for linear phase ) .\end{matrix}$$

The transformations from the frequency domain to the time domain and vice versa are done using the fast Fourier transform and inverse fast Fourier transform, respectively, by discretizing ω.

The pass-band and stop-band in the frequency domain are defined to be Ωₚ≡{ω: ωₚ<ω≦π and Ωₛ{ω: 0<ω≦ωₛ}, respectively. As discussed more fully below, the sets involved in designing the SIRF filter 120 in an exemplary embodiment are (i) a time domain convex set, C₁, representing the filters with linear phase; (ii) a frequency domain non-convex set, C₂ representing the non-linear phase filters with the appropriate constraints in the pass-band and stop-band; (iii) a frequency domain convex set, C₃, representing the linear phase filters with the appropriate constraints in the pass-band and stop-band; (iv) a time domain convex set, C₄, representing all the filters of length N; and (v) a time domain convex set, C₅ (n), for a specific range of values of n, (application dependent). Although C (n) consists of numerous convex sets, it is referred to hereinafter as C₅. More specifically, C₅ represents additional constraints on the filter h in the time domain. Thus, the time domain sets, C₁, C₄ and C₅, are convex, while the frequency domain sets, C₂ and C₃, are convex or non-convex for filters with linear or non-linear phase, respectively. The optional frequency domain set, C₃, constrains the filter such that it will have linear phase.

The sets may be defined mathematically as follows:

$$\begin{matrix}{C}_{1} ≡ \{ h ∈ {R}^{N} : h ( n ) = h ( N - 1 - n ) , for n = 0 , 1 , … , N - 1 \} , \\ {C}_{2} ≡ \{ \begin{matrix} h ∈ {R}^{N} : 1 - α \leq \vert H ( ω ) \vert \leq 1 + α for ω ∈ {Ω}_{p} \\ a n d \vert H ( ω ) \vert \leq β for ω ∈ {Ω}_{s}\end{matrix} \} , \\ {C}_{3} ≡ \{ \begin{matrix}h ∈ {R}^{N} : 1 - α \leq A ( ω ) \leq 1 + α \\ and Φ ( ω ) = - ω ( N - 1 ) / 2 for ω ∈ \\ \vert H ( ω ) \vert \leq β for ω ∈ {Ω}_{s} ,\end{matrix} {Ω}_{p} , \} , \\ {C}_{4} ≡ \{ h ∈ {R}^{N} \} , \\ {C}_{5} ( n ) ≡ \{ h ∈ {R}^{N} : {σ}_{n} \leq {( s * h )}_{n} \leq {ρ}_{n} \} ( 0 < n < N + M - 1 )\end{matrix}$$

where the vector s referenced in the definition for the set, C₅, is the impulse response of the channel, * denotes convolution, (s*h)ₙ denotes the response at time n, and σₙ and ρₙ represent the desired lower and upper bounds, respectively. M is the size of the discrete channel impulse response, s. R^{N} is the Hilbert space of dimension N.

Pᵢ is defined to be the projection operator onto the set Cᵢ. For a more detailed discussion of the computation of the projection operators and the VSPM algorithm generally, see, Henry Stark, “Vector Space Projection: A Numerical Approach to Signal and Image Processing, Neural Nets, and Optics,” (Wiley, 1998), incorporated by reference herein. The two iterative algorithms proposed are:

hₖ₊₁=P₂P₄P₅hₖ, where h₀ is arbitray and projection operators P₂, P₄ and P₅ are projected onto sets C₂, C₄, C₅ to produce a non-linear phase filter; or

hₖ₊₁=P₁P₃P₅hₖ, where hₒ is arbitray and projection operators P₁, P₃, and P₅ are projected onto sets C₁, C₃, C₅ to produce a linear-phase filter.

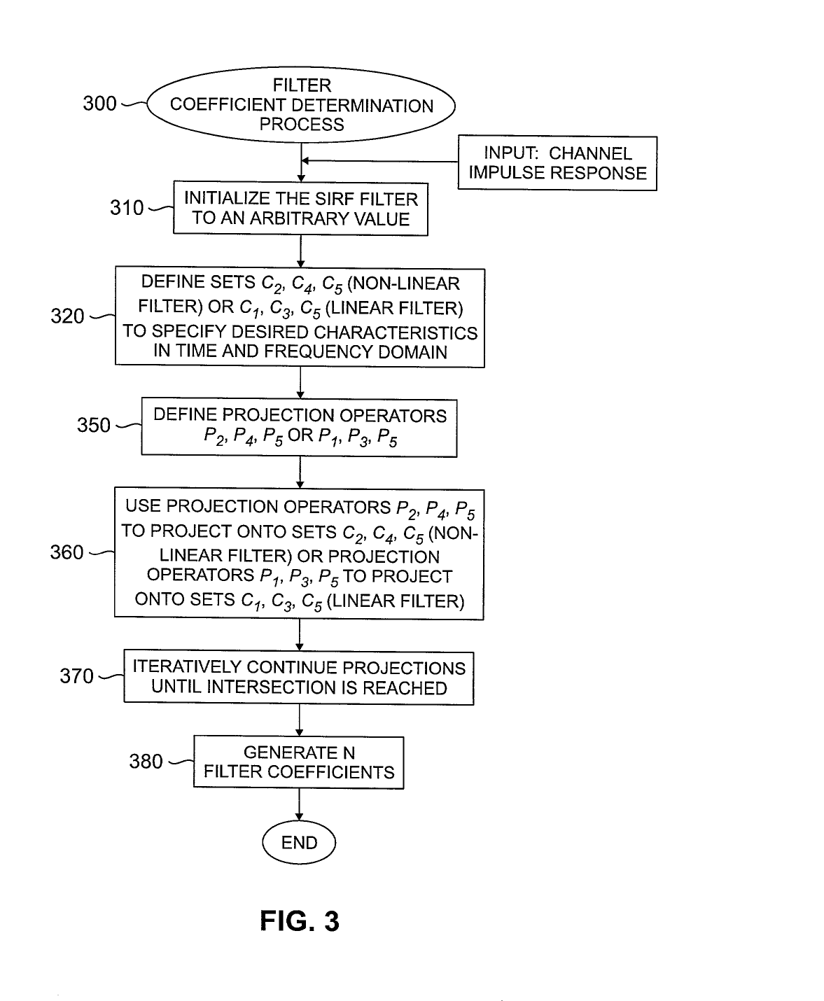

FIG. 2 is a schematic block diagram illustrating a modem 200 in which the present invention may be employed. As shown in FIG. 2, the modem 200 includes one or more communication ports 230 for receiving a signal from a communication channel 110. As previously indicated, the received signal is applied to a variable SIRF filter 120 in accordance with the present invention, before being applied to a decoder 240 that decodes the signal in a known manner. The coefficients for the SIRF filter 120 are determined by a filter coefficient determination process 300, discussed below in conjunction with FIG. 3.

The filter coefficient determination process 300 may be stored in a data storage device 220 that could be implemented as an electrical, magnetic or optical memory, or any combination of these or other types of storage devices. Moreover, the term “memory” should be construed broadly enough to encompass any information able to be read from or written to an address in the addressable space accessed by a processor (not shown). Alternatively, the filter coefficient determination process 300 may be embodied on an application specific integrated circuit (ASIC).

FIG. 3 is a flow chart describing the filter coefficient determination process 300 incorporating features of the present invention. As shown in FIG. 3, the filter coefficient determination process 300 receives the impulse response of the channel 110 as an input and then initializes the SIRF filter 120 to an arbitrary value during step 310 (to provide a starting point). Thereafter, the sets that specify the desired filter characteristics are defined during step 320. As discussed above, sets C₂, C₄, C₅ specify the desired characteristics in the time and frequency domains for a non-linear filter, while sets C₁, C₃, C₅ specify the desired characteristics in the time and frequency domains for a linear filter.

The corresponding projection operators P₂, P₄, P₅ or P₁, P₃, P₅ are defined during step 350, and are then used to project onto the corresponding sets C₂, C₄, C₅ or C₁, C₃, C₅ during step 360. As shown during step 370, the projections are continued iteratively until an intersection is reached. The intersection defines the filter coefficients for the SIRF filter 120, during step 380. Program control then terminates.

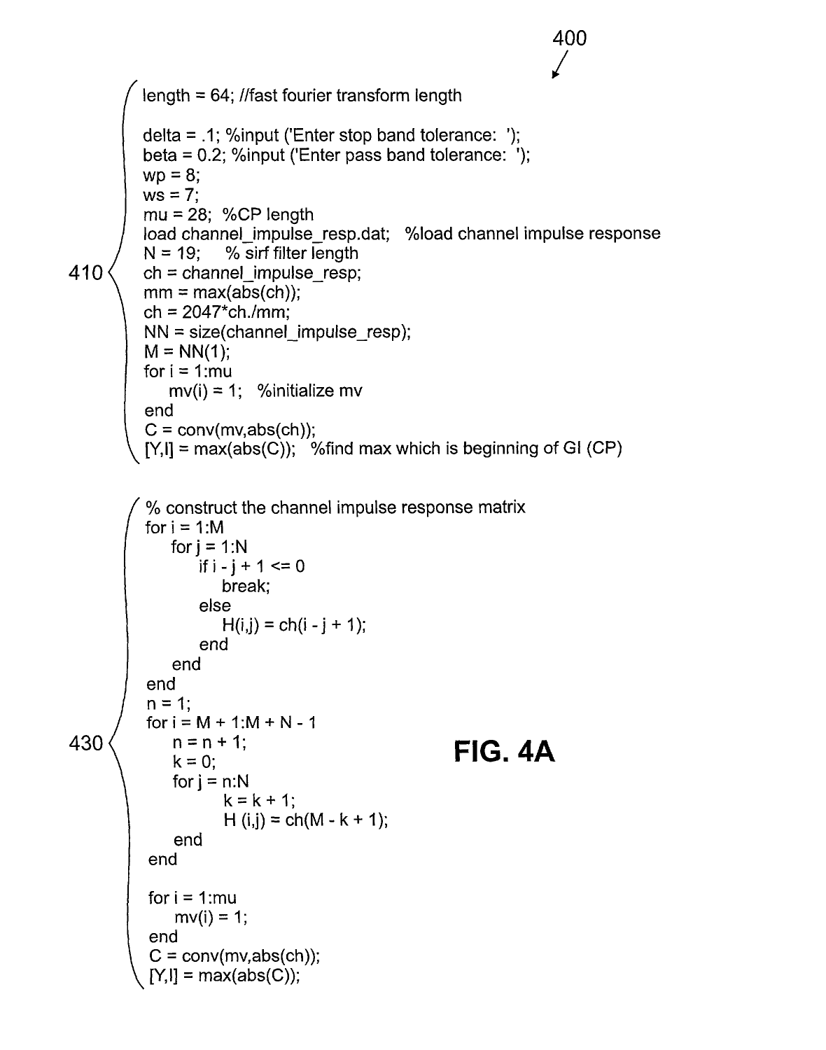

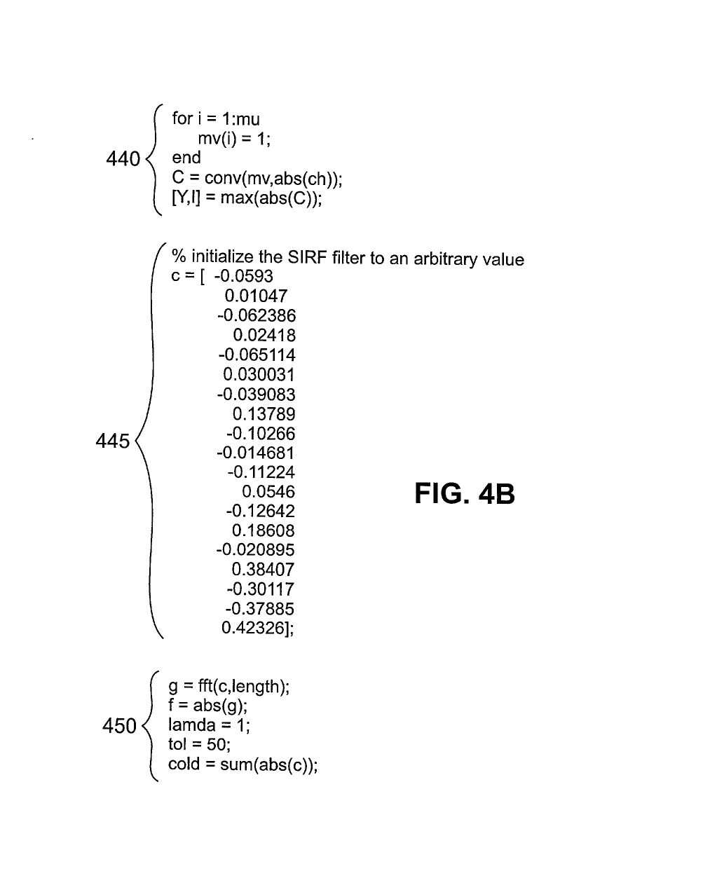

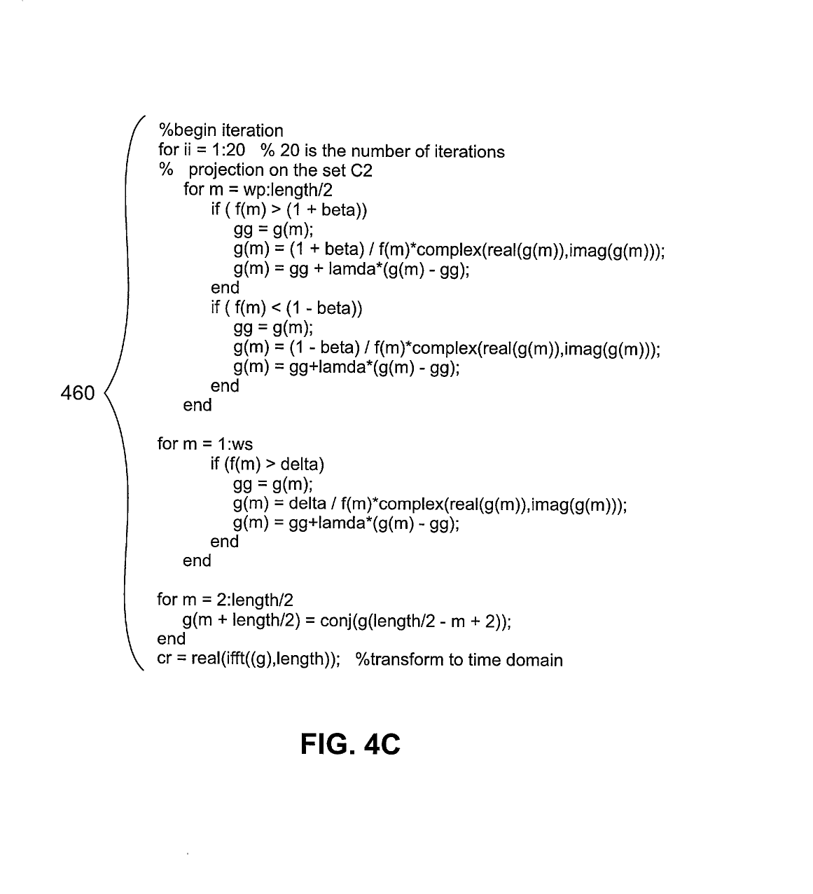

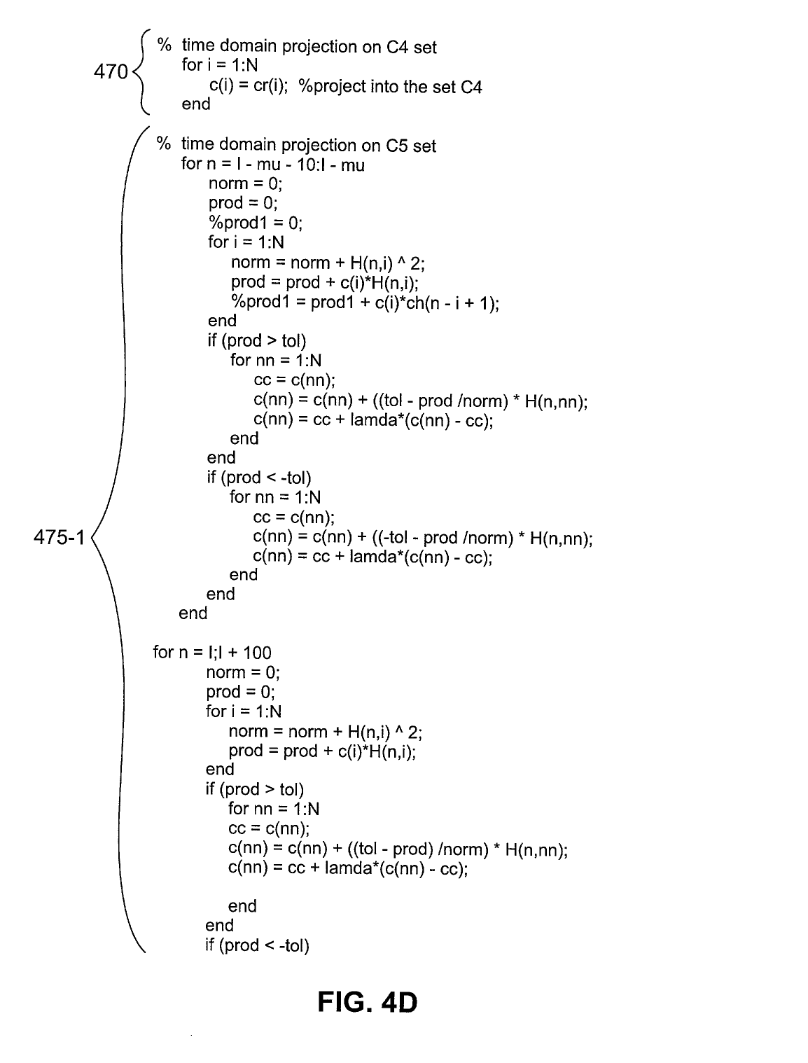

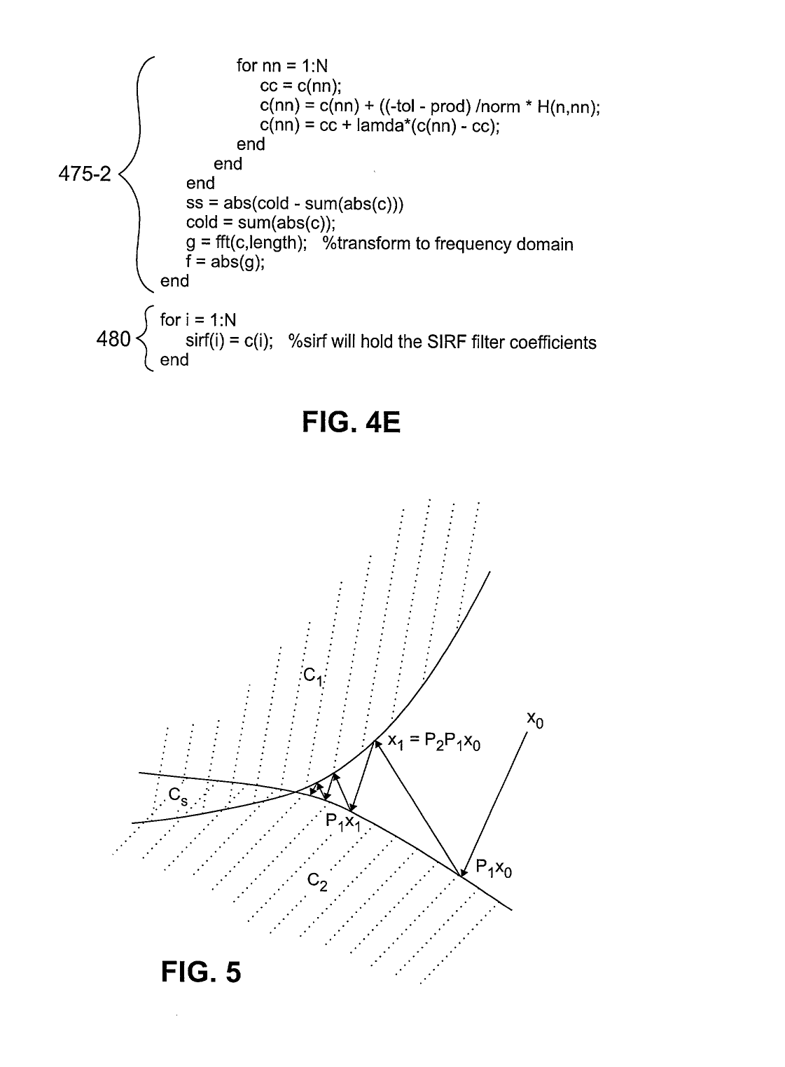

FIGS. 4A through 4E, collectively, illustrate exemplary pseudo-code 400 for generating a non-linear SIRF filter 120. As shown in FIG. 4A, the pseudo-code 400 has an initialization section 410 that initializes a number of parameters and loading the impulse response for the channel 110. Thereafter, a channel impulse response matrix is established in section 430. The channel impulse response matrix is used for convolution needed for projection onto the set C₅ As shown in FIG. 4B, the pseudo-code 400 then determines the maximum energy of the channel impulse response in section 440. The SIRF filter 120 is initialized to an arbitrary value in section 445, and a number of additional parameters are initialized during step 450.

As shown in FIG. 4C, the first iterative procedure is performed during section 460 to project onto the set C₂ using the projection operator P₂. The frequency-to-time transformation is then performed at the end of section 460 using an inverse Fourier transform. As shown in FIG. 4D, an iterative procedure is performed during section 470 to project onto the set C₄ using the projection operator P₄. As shown in FIGS. 4D and 4E, an iterative procedure is performed during section 475 (comprised of sections 475-1 (FIG. 4D) and 475-2 (FIG. 4E) to project the projection operator P₅ onto the set C₅ defining additional time characteristics. The time-to-frequency transformation is then performed at the end of section 475-2 using a Fourier transform. Finally, the determined filter coefficients are applied to the SIRF filter 120 during section 480 (FIG. 4E).

FIG. 5 illustrates the trajectory of iteration in VSPM for two exemplary sets, C₁ and C₂, until the two sets converge to an intersecting set satisfying the constraints of both sets. The solution set Cₛ is the intersection region and x₀ is an arbitrary starting point from which the first set is projected onto the second set (at a point defined by P₁X₀). Thereafter, the second set is projected onto the first set at a point x₁, where x₁ equals P₂P₁x₀.

It is to be understood that the embodiments and variations shown and described herein are merely illustrative of the principles of this invention and that various modifications may be implemented by those skilled in the art without departing from the scope and spirit of the invention.

I claim:

1. A method for determining coefficient values for a shortening impulse response filter (SIRF), said method comprising the steps of:
establishing at least one set defining constraints that said SIRF filter must satisfy in a time domain;
establishing at least one set defining constraints that said SIRF filter must satisfy in a frequency domain; and
determining an intersecting set of said at least one set defining said time domain constraints and said at least one set defining said frequency domain constraints.

2. The method according to claim 1, wherein said at least one set defining constraints that said SIRF filter must satisfy in a frequency domain define a filter having a linear phase.

3. The method according to claim 1, wherein said at least one set defining constraints that said SIRF filter must satisfy in a frequency domain define a filter having a non-linear phase.

4. The method according to claim 1, wherein said time domain constraints specify a shortening of a channel impulse response.

5. The method according to claim 1, wherein said frequency domain constraints include a frequency response for said SIRF filter that does not attenuate a received signal.

6. The method according to claim 1, wherein said frequency domain constraints include a pass-band for said SIRF filter.

7. The method according to claim 2, wherein said at least one set defining said frequency domain constraints is defined as follows:
$${C}_{2} ≡ \{ \begin{matrix} h ∈ {R}^{N} : 1 - α \leq \vert H ( ω ) \vert \leq 1 + α for ω ∈ {Ω}_{p} \\ an d \vert H ( ω ) \vert \leq β for ω ∈ {Ω}_{s}\end{matrix} \} ,$$
where h is the impulse response of length N that shortens the impulse response of a channel, H(ω) is the impulse response in the frequency domain, R^{N} is the Hilbert space of dimension N, Ωₚ is the pass-band and Ω_{S} is the stop-band.

8. The method according to claim 3, wherein said at least one set defining said frequency domain constraints is defined as follows:
$${C}_{3} ≡ \{ \begin{matrix}h ∈ {R}^{N} : 1 - α \leq A ( ω ) \leq 1 + α \\ and Φ ( ω ) = - ω ( N - 1 ) / 2 for ω ∈ \\ \vert H ( ω ) \vert \leq β for ω ∈ {Ω}_{s} ,\end{matrix} {Ω}_{p} , \} ,$$
where h is the impulse response of length N that shortens the impulse response of a channel, H(ω) is the impulse response in the frequency domain, R^{N} is the Hilbert space of dimension N, Ωₚ is the pass-band, Ω_{S} is the stop-band,
$$A ( ω ) = {\sum }_{0}^{N / 2 - 1} 2 h ( n ) cos [ ( n - \frac{N - 1}{2} ) ω ]$$
$$Φ ( ω ) = - \frac{N - 1}{2} ω .$$

9. The method according to claim 1, wherein said determining step further comprises the step of employing vector space projection methods to determine said intersecting set.

10. The method according to claim 9, wherein said vector space projection method is iteratively applied to said at least one set defining said time domain constraints and said at least one set defining said frequency domain constraints until said sets converge to a set of coefficients satisfying said time domain constraints and said frequency domain constraints.

11. A shortening impulse response filter (SIRF), comprising:
a set of finite impulse response (FIR) coefficients satisfying at least one constraint in a time domain and at least one constraint in a frequency domain, wherein said at least one time domain constraint is represented as at least one first set and wherein said at least one frequency domain constraint is represented as at least one second set, wherein said finite impulse response (FIR) coefficients are determined by an intersecting set of said at least one set defining said time domain constraints and said at least one set defining said frequency domain constraints.

12. The SIRF according to claim 11, wherein said at least one set defining constraints that said SIRF filter must satisfy in a frequency domain define a filter having a linear phase.

13. The SIRF according to claim 11, wherein said at least one set defining constraints that said SIRF filter must satisfy in a frequency domain define a filter having a non-linear phase.

14. The SIRF according to claim 11, wherein said time domain constraints specify a shortening of a channel impulse response.

15. The SIRF according to claim 11, wherein said frequency domain constraints include a frequency response for said SIRF filter that does not attenuate a received signal.

16. The SIRF according to claim 11, wherein said frequency domain constraints include a pass-band for said SIRF filter.

17. The SIRF according to claim 11, wherein said intersecting set is determined by employing vector space projection methods.

18. The SIRF according to claim 17, wherein said vector space projection method is iteratively applied to said at least one set defining said time domain constraints and said at least one set defining said frequency domain constraints until said sets converge to a set of coefficients satisfying said time domain constraints and said frequency domain constraints.

19. A system for determining coefficient values for a shortening impulse response filter (SIRF), said system comprising:
a memory that stores computer-readable code; and
a processor operatively coupled to said memory, said processor configured to implement said computer-readable code, said computer-readable code configured to:
establish at least one set defining constraints that said SIRF filter must satisfy in a time domain;
establish at least one set defining constraints that said SIRF filter must satisfy in a frequency domain; and
determine an intersecting set of said at least one set defining said time domain constraints and said at least one set defining said frequency domain constraints.

20. The system according to claim 19, wherein said at least one set defining constraints that said SIRF filter must satisfy in a frequency domain define a filter having a linear phase.

21. The system according to claim 19, wherein said at least one set defining constraints that said SIRF filter must satisfy in a frequency domain define a filter having a non-linear phase.

22. The system according to claim 19, wherein said time domain constraints specify a shortening of a channel impulse response.

23. The system according to claim 19, wherein said frequency domain constraints include a frequency response for said SIRF filter that does not attenuate a received signal.

24. The system according to claim 19, wherein said frequency domain constraints include a pass-band for said SIRF filter.

25. The system according to claim 20, wherein said at least one set defining said frequency domain constraints is defined as follows:
$${C}_{2} ≡ \{ \begin{matrix} h ∈ {R}^{N} : 1 - α \leq \vert H ( ω ) \vert \leq 1 + α for ω ∈ {Ω}_{p} \\ an d \vert H ( ω ) \vert \leq β for ω ∈ {Ω}_{s}\end{matrix} \} ,$$
where h is the impulse response of length N that shortens the impulse response of a channel, H(ω) is the impulse response in the frequency domain, RN is the Hilbert space of dimension N, Ωₚ is the pass-band and Ω_{S} is the stop-band.

26. The system according to claim 21, wherein said at least one set defining said frequency domain constraints is defined as follows:
$${C}_{3} ≡ \{ \begin{matrix}h ∈ {R}^{N} : 1 - α \leq A ( ω ) \leq 1 + α \\ and Φ ( ω ) = - ω ( N - 1 ) / 2 for ω ∈ \\ \vert H ( ω ) \vert \leq β for ω ∈ {Ω}_{s} ,\end{matrix} {Ω}_{p} , \} ,$$
where h is the impulse response of length N that shortens the impulse response of a channel, H(ω) is the impulse response in the frequency domain, R^{N} is the Hilbert space of dimension N, is the pass-band, Ω_{S} is the stop-band,
$$\begin{matrix}A ( ω ) = {\sum }_{0}^{N / 2 - 1} 2 h ( n ) cos [ ( n - \frac{N - 1}{2} ) ω ] and \\ Φ ( ω ) = - \frac{N - 1}{2} ω . \end{matrix}$$

27. The system according to claim 19, wherein said intersecting set is determined by employing vector space projection methods.

28. The system according to claim 27, wherein said vector space projection method is iteratively applied to said at least one set defining said time domain constraints and said at least one set defining said frequency domain constraints until said sets converge to a set of coefficients satisfying said time domain constraints and said frequency domain constraints.
